(19) United States
(12) Patent Application Publication
(10) Pub. No.: US 2021/0193735 A1
(43) Pub. Date: Jun. 24, 2021

(54) A MAGNETIC RANDOM ACCESS MEMORY STORAGE ELEMENT AND MAGNETIC RANDOM ACCESS MEMORY

(71) Applicant: INFORMATION TECHNOLOGIES CO., LTD., Shanghai (CN)

(72) Inventors: YIMIN GUO, SAN JOSE, CA (US); YUNSEN ZHANG, SHANGHAI (CN); JUN CHEN, FREMONT, CA (US); RONGFU XIAO, DUBLIN, CA (US)

(73) Assignee: Shanghai CiYu Information Technologies Co., Ltd, Shanghai (CN)

(21) Appl. No.: 16/490,548

(22) PCT Filed: Jun. 28, 2019
(86) PCT No.: PCT/CN2019/093736

§ 371 Date: Sep. 1, 2019

(30) Foreign Application Priority Data
Feb. 25, 2019 (CN) 201910138993.1

(51) Int. Cl. H01L 27/22; H01L 43/02; H01L 43/10; H01L 43/08; G11C 11/16; G11C 11/15

(52) U.S. Cl. CPC H01L 27/222; H01L 43/02; G11C 11/15; H01L 43/08; G11C 11/161; H01L 43/10

(57) ABSTRACT

The invention discloses a magnetic random access memory (MRAM) storage element and a magnetic random access memory. The MRAM storage element has a stack structure formed by subsequently stacking a reference layer, a tunnel barrier layer, a first free layer, a perpendicular magnetic coupling layer, a second free layer, and a magnetic damping barrier layer. The magnetization vector in the second free layer is perpendicular to the film surface, and is parallel to the magnetization in the first free layer through parallel magnetic coupling to the first free layer. The perpendicular magnetic coupling layer is used to achieve a strong magnetic coupling between the first free layer and the second free layer and to provide additional interface perpendicular magnetic anisotropies for both the first free layer and the second free layer. The magnetic damping barrier layer provides additional interface perpendicular magnetic anisotropy to the second free layer and reduces the magnetic damping coefficient of the second free layer. The addition of the second free layer in the invention increases the total thickness of the free layer, reduces the magnetic damping coefficient and increases the thermal stability factor, while the critical write current does not increase and the tunneling magnetoresistance is not affected.

### TECHNICAL FIELD & RELATED APPLICATION

The invention relates to the field of magnetic random access memory, in particular, a magnetic random access memory storage element with a double free layer and a magnetic random access memory (MRAM).

This application follows the priority to a Chinese patent application (No. 2019101389931) dated on Feb 25 2019 through PCT/CN2019/093736.

### TECHNICAL BACKGROUND

In recent years, MRAM based up on magnetic tunneling Junction (MTJ) is considered as the future solid-state non-volatile memory, which has the characteristics of high-speed read and write, large capacity and low energy consumption. Ferromagnetic MTJ is usually a sandwich structure, in which there is a magnetic recording layer (free layer), which can change the direction of magnetization to record different data; an insulated tunnel barrier layer located in the middle; and a magnetic reference layer located on the other side of the tunnel barrier layer, whose magnetization direction is unchanged.

In order to record information in this kind of magnetoresistance element, a writing method based on spin transfer Torque (STT) is proposed. Such MRAM is called STT-MRAM. According to the direction of magnetic polarization, STT-MRAM can be divided into in-plane STT-MRAM and perpendicular STT-MRAM (pSTT-MRAM) which have better performance. In the magnetic tunnel junction (MTJ) with perpendicular magnetic anisotropy (PMA), as the free layer of information storage, there are two magnetization states in the perpendicular direction, i.e. up and down, corresponding to “0” and “1” in the binary system, respectively. In practical applications, the direction of magnetization of the free layer remains unchanged when reading information or in an idle state; in the writing process, if there is a signal input of different states, the direction of magnetization of the free layer will be reversed 180 degrees in the perpendicular direction. The industry calls the ability of the free layer of magnetic memory to keep its magnetization direction unchanged under this idle state Data Retention or Thermal Stability. Requirements are different in different application scenarios. For a typical non-volatile memory (NVM), the thermal stability requirement is that the data can be stored for 10 years at 125° C.

In addition, as the core storage element of a magnetic random access memory (MRAM), MTJ element must be compatible with CMOS technology and be able to withstand long-term annealing at 400° C.

FIG. 1 is a schematic diagram of an existing storage element for magnetic random access memory. Free layer is generally composed of CoFeB, CoFe/CoFeB, Fe/CoFeB or CoFeB/(Ta, W, Mo, Hf)/CoFeB, which is equivalent to the first free layer in the patent of the invention. In order to improve the density of magnetic memory, the critical dimension or the size of magnetic tunnel junction has been made smaller and smaller in recent years. When the size of the magnetic tunnel junction is further reduced, the thermal stability factor of the magnetic tunnel junction will be dramatically reduced. For ultra-small size MRAM magnetic memory cells, methods to improve thermal stability are usually to reduce the thickness of free layer, saturation susceptibility of free layer or to increase interface anisotropy. If the thickness of the free layer is reduced, the tunneling magnetoresistance (TMR) will be reduced, which will increase the error rate in reading operation. If the thickness is unchanged, changing the free layer into the material with a lower saturation magnetization will also reduce the TMR, which is not desired for the reading operation of the device.

### CONTENT OF INVENTION

In order to solve the problems of the existing technology, the present invention provides a magnetic random access memory storage element with two free layers and a magnetic random memory, in which a perpendicular coupling layer and a second free layer is inserted between the first free layer and the cover layer of a magnetic random access memory (MRAM) with perpendicular magnetic anisotropy (PMA). The technical scheme is as follows:

On the one hand, the present invention provides a magnetic random access memory storage element with two free layers, including a reference layer, a barrier layer, a first free layer, a perpendicular coupling layer, a second free layer and a magnetic damper barrier layer. The magnetization vector in the second free layer is always perpendicular to the interface of the first free layer and is aligned with the magnetization vectors in the first free layer.

The first free layer further includes a stack of first free sublayer, a first insertion sublayer, and a second free sublayer. The perpendicular magnetic coupling layer is arranged between the stack of the first free layer and the second free layer. The perpendicular magnetic coupling layer is used to realize the magnetic coupling between the first free layer and the second free layer.

Further, the material for the second free layer is selected from Fe, Co, Ni, CoFe, FeB, CoB, W, Mo, V, Nb, Cr, Hf, Ti, Zr, Ta, Sc, Y, Zn, Ru, Os, Ru, Rh, Ir, Pd, Pt and CoFeB.

Further, the second free layer includes a structure selected from the group consisting of CoFeB, CoFe/CoFeB, Fe/CoFeB, Fe/CoFeB, Fe/CoFeB, CoFeB/X/CoFeB, Fe/FeB, Fe/CoFeB/X/CoFeB and CoFe/CoFeB/X/CoFeB, with X here being a non-magnetic metal selected from the group consisting of W, Mo, V, Nb, Cr, Hf, Ti, Zr, Ta, Sc, Y, Zn, Ru, Os, Rh, Ir, Pd and Pt, or multiple insertion of a non-magnetic metal X in between the structure of CoFeB, CoFe/CoFeB, Fe/CoFeB.

Further, the second free layer includes a structure of CoFeB/X/CoFeB, with the first CoFeB layer having a thickness of 0.2 nm or more but 1.4 nm or less, and an atomic ratio of Co:Fe is in the range from 1:3 to 3:1, the atomic percentage of B is 15% or more but 40% or less, and the second layer X is a non-magnetic metal with material selected from the group consisting of W, Mo, V, Nb, Cr, Hf, Ti, Zr, Ta, Sc, Y, Zn, Ru, Os, Ru, Rh, Ir, Pd and/or Pt with a thickness of 0.1 nm or more but 0.6 nm or less, and the third layer CoFeB having a thickness of 0.2 nm or more but 1.0 nm or less, the atomic ratio of Co:Fe is in the range from 1:3 to 3:1, and the atomic percentage of B is 15% or more but 40% or less. The total thickness of the second free layer is 0.5-2 nm.

Further, the barrier layer is made of one non-magnetic metal oxide selected from the group consisting of MgO, MgZnₓO_{y}, MgBₓO_{y} and MgAlₓO_{y}.

Further, the first free layer possesses a variable magnetic polarization. The first free layer includes a structure selected from the group consisting of CoFeB, CoFe/CoFeB, Fe/CoFeB, CoFeB/X/CoFeB, Fe/CoFeB/X/CoFeB and CoFe/CoFeB/X/CoFeB, with X being a non-magnetic metal selected from the group consisting of W, Mo, V, Nb, Cr, Hf, Ti, Zr, Ta, Sc, Y, Zn, Ru, Os, Ru, Rh, Ir, Pd, Pt.

On the other hand, the invention provides a magnetic random access memory, which includes the storage element mentioned above, and also includes bottom electrode, seed layer, anti-parallel ferromagnetic superlattice layers, crystalline-lattice insolation layer, covering layer and top electrode. The bottom electrode, seed layer, anti-parallel ferromagnetic superlattice stack, crystalline-lattice insolation layer, reference layer, barrier layer, first free layer and ferromagnetic coupling layer and second free layer are also provided. The magnetically damped barrier layer, the covering layer and the top electrode are stacked in sequence.

Further, the antiparallel ferromagnetic superlattice stack comprises a lower ferromagnetic superlattice layer, an antiparallel ferromagnetic coupling layer and an upper ferromagnetic layer. The antiparallel ferromagnetic superlattice layer comprises a structure selected from the group consisting of [Co/Pt]n/Co/(Ru,Ir,Rh), [Co/Pt]n/Co/(Ru,Ir,Rh)/(Co, Co[Pt/Co]m), [Co/Pd]n/Co/(Ru,Ir,Rh), [Co/Pd]n/Co/(Ru,Ir,Rh)/(Co,Co[Pd/Co]m), and [Co/Ni]n/Co/ (Ru,Ir,Rh), [Co/Ni]n/Co/(Ru,Ir,Rh)/(Co,Co[Ni/Co]m.

Further, the bottom electrode is made of at least one material selected from the group consisting of Ti, TiN, Ta, TaN, W, WN.

The top electrode is made of at least one material selected from the group consisting of Ta, TaN, Ti, TiN, W, WN.

Further, the seed layer is made of at least one material selected from the group consisting of Ta, Ti, TiN, TaN, W, WN, Ru, Pt, Ni, Cr, NiCr, CrCo, CoFeB. The seed layer has a multi-layer structure selected from the group consisting of Ta/Ru, Ta/Pt and Ta/Pt/Ru.

The crystalline-lattice isolation layer is made of one material selected from the group consisting of Ta, W, Mo, Hf, Fe, Co (Ta, W, Mo or Hf), Fe (Ta, W, Mo or Hf), FeCo (Ta, W, Mo or Hf) and FeCoB (Ta, W, Mo or Hf).

The cap layer is made of one material selected from the group consisting of W, Mo, Mg, Nb, Ru, Hf, V, Cr and Pt material. The cover layer has a double-layer structure of (W, Mo, Hf)/Ru or tri-layer structure of Pt/(W, Mo, Hf)/Ru.

Further, after deposition of the bottom electrode, the seed layer, the antiparallel ferromagnetic superlattice layer, the crystalline-lattice isolation layer, the layer, barrier layer, the first free layer, the perpendicular coupling layer, the magnetic damping barrier layer, the cap layer and the top electrode, the film stack is annealed at 400° C. for least 90 minutes.

The magnetic random access memory storage element disclosed by the invention with a thermal stability enhancement layer can produce the following beneficial effects: the additional second free layer in the invention does not affect TMR, increases the total thickness of the free layer, reduces the damping coefficient and increases the thermal stability factor, while the critical write current does not increase.

a. The second free layer and the first free layer form a ferromagnetic coupling. Under the condition of thermal disturbance or external magnetic field, if the magnetization vector of the free layer is to be reversed, it must provide more energy than the sum of the energy barrier of the free layer and the energy barrier of the thermal stability enhancement layer, which greatly improves the thermal stability.

b. The addition of the second free layer has no effect on TMR.

c. Non-magnetic metal oxide layers selected from the group consisting of MgO, MgZnₓO_{y}, MgBₓO_{y} and MgAlₓO_{y} are deposited before and after the deposition of the second free layer, with a thicknesses of 0.3-1.5 nm (before) and 0.5-3.0 nm (after), respectively, which provide additional sources of interfacial anisotropy, thus further increase thermal stability. In addition, the addition of magnetic damper barrier layer above the second free layer can effectively reduce the damping coefficient of the whole film stack, which is conducive to the reduction of write current.

d. Can withstand long time annealing at 400° C.

e. The addition of the second free layer increases the total thickness of the free layer, which is conducive to the reduction of the damping coefficient, so that the critical write current does not increase.

### DESCRIPTION OF DRAWINGS

In order to more clearly illustrate the technical scheme in the embodiments of the present invention, the drawings to be used in the description of the embodiments will be briefly described below. Obviously, the drawings described below are only some embodiments of the present invention. For those skilled in the field, other drawings can be obtained from these drawings without any creative effort.

FIG. 1 is a schematic diagram of a storage element of a magnetic random access memory in the prior art.

FIG. 2 is a schematic structure diagram of a storage element of a magnetic random access memory provided for an embodiment of the present invention.

FIG. 3 is a schematic structure diagram of a storage element of a magnetic random access memory provided in a preferred embodiment of the present invention.

FIG. 4 is a schematic diagram of a reversal behavior of the second free layer under an external magnetic field before and after the addition of the second free layer provided by the embodiment of the present invention.

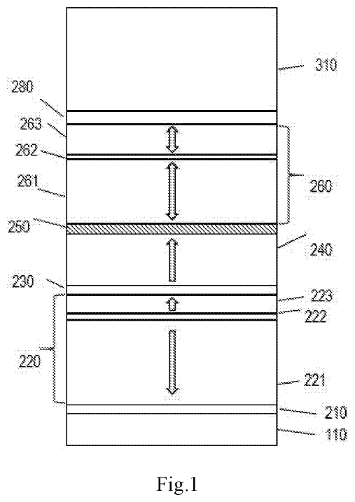

Among the figures, the reference marks include 110—bottom electrode, 210—seed layer, 220—stack of antiparallel ferromagnetic superlattice, 221—lower ferromagnetic layer, 222—antiparallel ferromagnetic coupling layer, 223—upper ferromagnetic layer, 230—crystalline-lattice isolation layer, 240—reference layer, 250—barrier layer, 260—stack of first free layer, 261—first free sublayer (I), 262—first insertion layer (II), 263—second free sublayer (III), 271—perpendicular coupling layer, 272—stack of second free layer, 272a—third free sublayer (I), 272b—second insertion layer(II), 272c—fourth free sublayer(III), 273—magnetically damped barrier layer, 280—cap layer, 310—top electrode.

### SPECIFIC EMBODIMENTS

In order to better understand the idea of the present invention for those in the technical field, the technical scheme in the embodiments of the present invention will be described clearly and completely in the light of the drawings in the embodiments of the present invention. Obviously, the embodiments described here are only one part of the embodiments of the present invention, not all of the embodiments. Based on the embodiments of the present invention, all other embodiments acquired by ordinary skills in the field without creative work shall fall within the scope of protection of the present invention.

It should be noted that the terms “first” and “second” in the description and claims of the present invention and the above-mentioned drawings are used to distinguish similar objects rather than to describe a particular order or orders. It should be understood that the data used in this way may be interchangeable in appropriate cases so that the embodiments of the present invention described herein can be implemented in a sequence other than those illustrated or described herein. In addition, the terms “include” and “have” and any variations of them are intended to cover non-exclusive inclusions, such as processes, methods, devices, products or equipment that contain a series of steps or units, which need not be limited to those clearly listed steps or units, but may include processes, methods, products or equipment that are not clearly listed or are inherent to them.

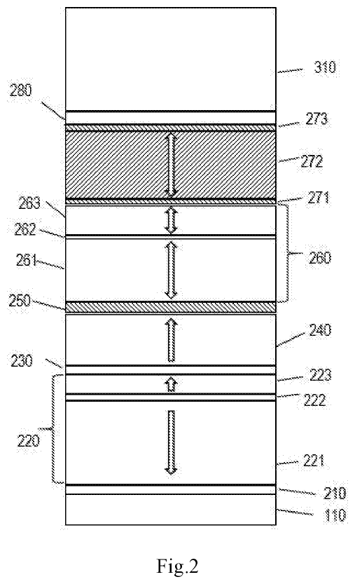

In one embodiment of the present invention, a magnetic random access memory storage element with two free layers is provided, in which a magnetic coupling layer and a second free layer are deposited between the top of the first free layer and the capping layer without vacuum interruption during the physical vapor deposition (PVD) of the magnetic tunnel junction multilayer. As shown in FIG. 2, the magnetic random access memory storage element with double free layers comprises a reference layer 240, a barrier layer 250, a first free layer 260, a perpendicular coupling layer 271, a second free layer 272, a magnetic damping barrier layer 273. The magnetization vectors in the first free layer and second free layer are parallel each other and always perpendicular to the surface of the free layers.

The stack of first free layer 260 includes the first free sublayer (I) 261, the first insertion layer (II) 262 and the second free sublayer (III) 263. The perpendicular coupling layer 271 is set between the first free layer 260 and the second free layer 272, which is used to establish a magnetic coupling between the first free layer 260 and the second free layer 272.

In a better embodiment of the present invention for a magnetic random access memory (MRAM), in addition to the storage element described above, also include bottom electrode 110, seed layer 210, antiparallel ferromagnetic superlattice 220, crystalline-lattice isolation layer 230, cover layer 280 and top electrode 310. The bottom electrode 110, seed layer 210, antiparallel ferromagnetic superlattice 220, crystalline-lattice isolation layer 230, reference layer 240, barrier 250, the first free layer 260, the perpendicular coupling layer 271, the second free layer 272, the magnetic damping barrier layer 273, the cover layer 280 and the top electrode 310 are stacked in sequence.

Among them, the bottom electrode 110 is made of at least one material selected from the group consisting of Ti, TiN, Ta, TaN, W and WN, which is usually formed by physical vapor deposition (PVD). After deposition, its surface is usually under flattening treatment to obtain a good surface smoothness for the deposition of magnetic tunnel junction.

Seed layer 210 is generally made of at least a material selected from the group consisting of Ta, Ti, TiN, TaN, W, WN, Ru, Pt, Ni, Cr, CrCo and CoFeB. Further, it can be multi-layer structures such as Ta/Ru, Ta/Pt or Ta/Pt/Ru, to facilitate the crystal structure of the subsequent antiferromagnetic layer 220.

Anti-Parallel Magnetic Supper-lattice 220 is also called Synthetic Anti-Ferrimagnet (SyAF), which is generally composed of [Co/Pt]n/Co/(Ru,Ir,Rd), [Co/Pd]n/Co/(Ru, Ir, Rh), [Co/Pt]n/Co/(Rh), [Co/Pd]/Co/[Pd/Co]m,[Co/Ni]n/Co/(Ru, Ir, Rh) or [Co/Ni]n/Co/(Ru, Ir, Rh)/(Co, Co[Ni/Co]m), and anti-parallel ferromagnetic superlattice 220 possesses a strong perpendicular magnetic anisotropy (PMA).

Reference layer 240 is magnetically polarized invariant under the ferromagnetic coupling of antiparallel ferromagnetic superlattice 220, and are generally composed of Co, Fe, Ni, CoFe, CoFeB or their combination. Since the anti-parallel ferromagnetic superlattice layer 220 has a face-centered cubic (FCC) crystal structure and the reference layer 140 has a body-centered cubic (BCC) crystal structure, the two crystalline lattices do not match. In order to realize the transition and ferromagnetic coupling from the anti-parallel ferromagnetic superlattice 220 to the reference layer 240, a layer of crystalline-lattice breaking 230 is usually added between the two layers, and its material is generally Ta, W, Mo, Hf Fe, Co (Ta, W, Mo or Hf), Fe (Ta, W, Mo or Hf), FeCo (Ta, W, Mo or Hf) or FeCoB (Ta, W, Mo or Hf) etc.

The barrier layer 250 is a non-magnetic metal oxide, and favorite materials include MgO, MgZnₓO_{y}, MgBₓO_{y} and MgAlₓO_{y}, and among which MgO is preferred.

The first free layer 260 has variable magnetic polarization, is generally made of a material selected from the group consisting of CoFeB, CoFe/CoFeB, Fe/CoFeB, CoFeB/X/CoFeB, Fe/CoFeB/X/CoFeB and CoFe/CoFeB/X/CoFeB, with X being selected from the materials W, Mo,V, Nb, Cr, Hf, Ti, Zr, Ta, Sc, Y, Zn, Ru, Os, Ru, Rh, Ir, Pd, Pt, can be further selected from CoFeB/X/CoFeB , Fe/CoFeB/X/CoFeB and CoFe/CoFeB/X/CoFeB. Taking the first free layer structure as an example, in this case, CoFeB/X/CoFeB represents a tri-layer layer structure, with the first and third layers made of CoFeB, and the middle layer X is made of at least metal element selected from the group consisting of W, Mo, V, Nb, Cr, Hf, Ti, Zr, Ta, Sc, Y, Zn, Ru, Os, Ru, Rh, Ir, Pd and Pt. The following structure is expressed in the same way, without further explanation.

The second free layer 272 maintain the same magnetization direction as the first free layer 260, and the materials used are similar to that of the first free layer, which is generally composed of at least a single element selected from the group consisting of Fe, Co, Ni, CoFe, FeB, CoB, W, Mo, V, Nb, Cr, Hf, Ti, Zr, Ta, Sc, Y, Zn, Ru, Os, Ru, Ru, Rh, Ir, Pd, Pt and CoFeB,and more specifically made of one structure selected from the group consisting of CoFeB, CoFe/CoFeB, Fe/CoFeB, CoFeB/(W,Mo,V,Nb,Cr,Hf)/CoFeB, Fe/CoFeB/(W,Mo,V,Nb,Cr,Hf,Ti,Zr,Ta,Sc,Y,Zn, Ru,Os,Ru,Rh, Ir,Pd,Pt)/CoFeB and CoFe/CoFeB/(W,Mo,V,Nb,Cr,Hf,Ti,Zr,Ta,Sc, Y,Zn,Ru,Os,Ru,Rh,Ir,Pd,Pt)/CoFeB, where CoFeB,CoFe/CoFeB,Fe/CoFeB may have multiple insertions of non-magnetic metals selected from the group consisting of W,Mo,V,Nb,Cr,Hf,Ti,Zr,Ta,Sc,Y,Zn,Ru, Os, Ru,Rh,Ir,Pd,and Pt with a total thickness of 0.5 nm or more but 2 nm or less. In a specific process, the material composition can be changed by adjusting the deposition conditions of PVD, and plasma etching process can be added to modify the material to obtain the best performance.

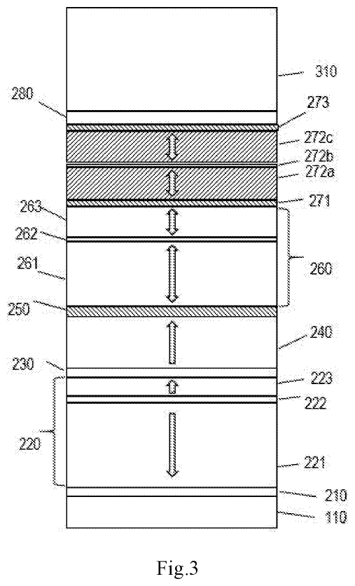

Further, as shown in FIG. 3, in a better implementation of the invention, CoFeB/(W, Mo, V, Nb, Cr, Hf, Ti, Zr, Ta, Sc, Y, Zn, Ru, Os, Ru, Rh, Ir, Pd, Pt)/CoFeB is selected as the second free layer, which includes the third free sublayer 272A and the second insertion layer 272B and the fourth free sublayer (III) 272C, in which the first layer is CoFeB with a thickness between 0.2 nm and 1.4 nm with atomic percentage of 15%˜40% for B, and the remaining Co:Fe with an atomic ratio ranging from 3:1 to 1:3, and the second layer is non-magnetic metal selected from W, Mo, V, Nb, Cr, Hf, Ti, Zr, Ta, Sc, Y, Zn, Ru, Os, Ru, Rh, Ir, Pd and/or Pt, and The thickness of the third layer of CoFeB is 0.2-1.0 nm. The atomic ratio of Co:Fe can be adjusted from 3:1 to 1:3. The atomic percentage of B is 15%-40%. By changing the PVD parameters such as deposition power or pressure, the thermal stability enhancement layer can achieve the best effect and selectively be placed in the second layer of CoFeB. After that, plasma etching was used to modify it.

Before and after the deposition of the second free layer 272, a layer of non-magnetic metal layer is usually deposited, with at least a material selected from MgZnₓO_{y}, MgBₓO_{y} and MgAlₓO_{y}, and preferably MgO can be selected, with a thickness ranging between 0.3 nm˜1.5 nm (before) and 0.5 nm˜3.0 nm (after), respectively. This can also provide a source of interfacial anisotropy, thereby increasing thermal stability. In addition, the addition of magnetically damped barrier 273 after the second free layer 272 effectively reduces the damping coefficient of the whole film structure, which is conducive to the reduction of writing current.

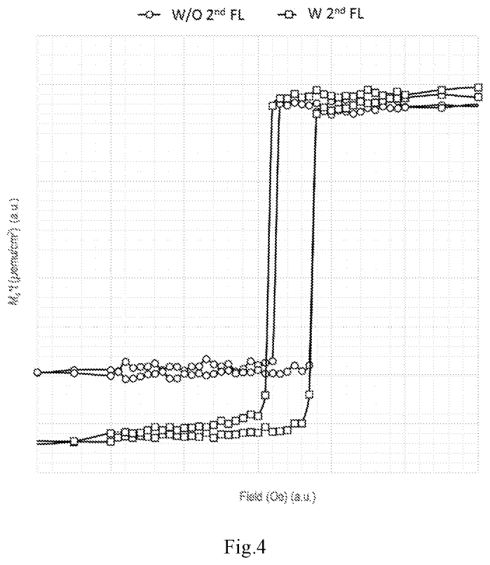

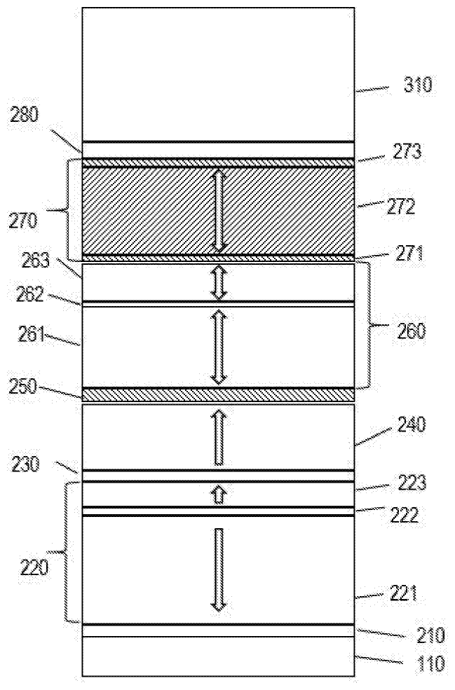

FIG. 4 is a better example of the present invention. Before and after the addition of the second free layer, the flip behavior of the free layer under an external magnetic field can be clearly seen that after the addition of the second free layer, Mst (saturation moment Ms times film thickness t) increases a lot, which is equivalent to the precondition of unchanged Hk and Ms, and increases the thickness of the free layer, thereby increasing the thermodynamic barrier of the free flip.

The cap layer 280 is made of at least one metal element selected from the group consisting of W, Mo, Mg, Nb, Ru, Hf, V, Cr and Pt, etc. with a preferred structure of (W, Mo, Hf)/Ru or/Pt/(W, Mo, Hf)/Ru.

Top electrode 290 is made of at least one structure selected from the group consisting of Ta, TaN, TaN/Ta, Ti, TiN, TiN/Ti, W, WN and WN/W.

After deposition of entire film stack, annealing at 400° C. for 90 minutes is performed, and the state of the reference layer, the first free layer and the second free layer was changed from amorphous to body-centered cubic (BCC) crystalline structure.

The thermal stability enhancement layer of the magnetic random access memory provided by the present invention is the second free layer between the top of the first free layer and the capping layer by a physical vapor deposition (PVD) process without a vacuum interruption.

In the second free layer, the magnetization vector is always perpendicular to the surface of the first free layer and parallel to the magnetization vector in the first free layer. Because the second free layer and the first free layer form a ferromagnetic coupling, any attempt to reverse the magnetization vector of the first free layer under a thermal disturbance or external magnetic field, must overcome the total energy barrier for both the first free layer and the second free layer.

Experiments show that the addition of second free layer does not affect TMR.

At the same time, a layer of non-magnetic metal is deposited before and after the deposition of the second free layer. The materials are MgO, MgZnₓO_{y}, MgBₓO_{y} and MgAlₓO_{y}, Mg or their combination, which can provide an additional source of interfacial anisotropy and increase thermal stability. In addition, due to the addition of the magnetic damping barrier layer above the second free layer, the damping coefficient of the whole film structure is effectively reduced, which is beneficial to the reduction of the writing current.

Ta and its nitrides have been successfully avoided in the selection of the first free-layer material and the covering material, so that it can withstand long annealing at 400° C.

Furthermore, due to the addition of the second free layer, the total thickness of free layer is increased, which is conducive to the reduction of damping constant (α). In the meantime, the materials with low damping coefficient can be selected for coupling layer and covering layer in the first free layer and second free layer, which can further reduce the damping coefficient. Although the thermal stability factor may increase, the critical write current does not increase due to the decrease of the damping coefficient.

Further, the Data Retention can be calculated using the following formula:

$$τ = {τ}_{0} exp ( \frac{E}{{k}_{B} T} ) \qquad ( 1 )$$

Among them, τ is the time of constant magnetization vector under thermal disturbance, τ₀ is the trial time (usually 1 ns), E is the energy barrier of free layer, k_{B} is the Boltzmann constant, T is the working temperature.

Thermal stability factor can be expressed as follows:

$$Δ = \frac{E}{{k}_{B} T} = \frac{{K}_{eff} V}{{k}_{B} T} = \{ \begin{matrix}[ ( {K}_{V} - 2 π {M}_{s}^{2} ( 3 {N}_{Z} - 1 ) ) t + {K}_{i} ] \frac{{π ( CD )}^{2}}{4 {k}_{B} T} , ( if CD < k ) \\ \frac{{π}^{3} {A}_{s}}{4 {k}_{B} T} t , ( if CD > k )\end{matrix} \qquad ( 2 )$$

Among them, K_{eff} is the effective anisotropic energy density of the free layer, V is the volume of the free layer, K_{V} is the volume anisotropic constant, Ms is the saturated susceptibility of the free layer, Nz is the demagnetization constant in the perpendicular direction, t is the thickness of the free layer, Ki is the interface anisotropic constant, CD is the critical dimension of the magnetic random access memory (i.e. the diameter of the free layer), As is a stiffness integral exchange constant, k is a critical size of the transition for a free-layer flip mode from domain flip (i.e., Magnetization switching processed by “macro-spin” switching) to reversed domain nucleation propagation (i.e., Magnetization switching processed by nucleation of a reversed domain and propagation of a domain wall). Experiments show that a thicker free layer favors in-plane anisotropy, and a thinner free layer helps out-plane perpendicular anisotropy. K_{V} can generally be neglected, while the contribution of demagnetization energy to perpendicular anisotropy is negative. Therefore, the perpendicular anisotropy comes entirely from the interface effect (Ki).

In addition, as the volume of the magnetic free layer decreases, the spin polarization current injected into the writing or conversion operation decreases, and the critical current I_{c0} of the writing operation is strongly related to the thermal stability. The relationship between the critical current I_{c0} and the thermal stability can be expressed as follows:

$${I}_{C 0} = \frac{4 e α {k}_{B} T}{ℏη} Δ \qquad ( 3 )$$

Among them, α is the damping constant, [symbol] is the reduced Planck constant and η is the spin polarizability.

The addition of the second free layer of the invention increases the thickness of the free layer, reduces the damping coefficient and increases the thermal stability factor, but neither affect TMR nor increase the critical write current.

The above are only a few better embodiments of the present invention, and are not intended to limit the present invention. Any modification, equivalent replacement, improvement, etc. made within the spirit and principles of the present invention shall be included in the scope of protection of the present invention.

1. A storage element of magnetic random access memory (MRAM) with t free layers has a stack structure formed by subsequently stacking a reference layer, a tunnel barrier layer, a first free layer, a perpendicular ferromagnetic coupling layer, a second free layer, a magnetic damping barrier layer and a cap layer; wherein the perpendicular ferromagnetic coupling layer provides additional perpendicular magnetic anisotropies for both the first and the second free layers and strong ferromagnetic coupling between the first and the second free layers; the first magnetization of the first free layer and the second magnetization of the second free layer are always perpendicular to the plane of the first free layer and the plane of the second free layer, respectively;
wherein the magnetic damping barrier layer provides a perpendicular interface anisotropy to the second free layer, and reduces the magnetic damping coefficient for the second free layer.

2. The element of claim 1 wherein the perpendicular ferromagnetic coupling layer is made of at least one material selected from the group consisting of MgO, MgZnₓO_{y}, MgBₓO_{y} and MgAlₓO_{y}, and has a thickness of 0.3 nm or more but 1.5 nm or less.

3. The element of claim 1 wherein the magnetic damping barrier layer is made of at least one material selected from the group consisting of MgO, MgZnₓO_{y}, MgBₓO_{y} and MgAlₓO_{y}, and has a thickness of 0.5 nm or more but 3.0 nm or less.

4. The element of claim 1 wherein the tunnel barrier layer is made of one material selected from the group of non-magnetic metal oxides including MgO, MgZnₓO_{y}, MgBₓO_{y} and MgAlₓO_{y}.

5. The element of claim 1 wherein the first free layer includes a structure selected from the group consisting of CoFeB, CoFe/CoFeB, Fe/CoFeB, CoFeB/X/CoFeB, Fe/CoFeB/X/CoFeB, and CoFe/CoFeB/X/CoFeB, with X being a non-magnetic metal selected from the group consisting of W, Mo,V, Nb, Cr, Hf, Ti, Zr, Ta, Sc, Y, Zn, Ru, Os, Ru, Rh, Ir, Pd, Pt.

6. The element of claim 1 wherein the second free layer includes a structure selected from the group consisting of CoFeB, CoFe/CoFeB, Fe/CoFeB, Fe/CoFeB, Fe/CoFeB, CoFeB/X/CoFeB, Fe/FeB, Fe/CoFeB/X/CoFeB and CoFe/CoFeB/X/CoFeB, with X being non-magnetic metal selected from the group consisting of W, Mo, V, Nb, Cr, Hf, Ti, Zr, Ta, Sc, Y, Zn, Ru, Os, Rh, Jr, Pd and Pt, or multiple insertion of a non-magnetic metal X in-between the structure of CoFeB, CoFe/CoFeB, Fe/CoFeB; the total thickness of the second free layer is 0.5 nm or more but 2 nm or less.

7. A magnetic random access memory (MRAM) includes any of the storage element described in claim 1, also includes a bottom electrode, a seed layer, an antiparallel ferromagnetic superlattice layer, a crystalline-lattice insolation layer, a covering layer and a top electrode; wherein the bottom electrode, seed layer, antiparallel ferromagnetic superlattice layer, crystalline-lattice insolation layer, reference layer, barrier layer, first free layer, ferromagnetic coupling layer, second free layer, magnetic damping barrier layer, covering layer and top electrode are stacked in sequence.

8. The element of claim 7 wherein the bottom electrode is composed of a material selected from Ti, TiN, Ta, TaN, W, WN or a combination of these materials; the top electrode is made of at least one material selected from the group consisting of Ta, TaN, Ti, TiN, W, WN.

9. The element of claim 7 wherein the seed layer is made of at least a material selected from the group consisting of Ta, Ti, TiN, TaN, W, WN, Ru, Pt, Cr, Ni, NiCr, CrCo and CoFeB. The seed layer has a multi-layer structure selected from the group consisting of Ta/Ru, Ta/Pt and Ta/Pt/Ru; wherein the crystalline-lattice insulation layer is made of a material selected from the group consisting of Ta, W, Mo, Hf, Fe, Co (Ta, W, Mo or Hf), Fe (Ta, W, Mo or Hf), FeCo (Ta, W, Mo or Hf), and FeCoB (Ta, W, Mo or Hf). wherein the cap layer is made of a material selected from the group consisting of W, Mo, Mg, Nb, Ru, Hf, V, Cr and Pt. The cover layer has a double-layer structure (W, Mo, Hf)/Ru or a tri-layer structure Pt/(W, Mo, Hf)/Ru.

10. The element of claim 7 wherein the magnetic random access memory the stack of the seed layer, the antiparallel ferromagnetic superlattice layer, the crystalline-lattice insulation layer, the reference layer, the tunnel barrier layer, the first free layer, the ferromagnetic coupling layer, the second free layer, the magnetic damping barrier layer, and the cap layer is deposited and annealed for at least 90 minutes at 400° C.
